(19) United States
(12) Patent Application Publication
(10) Pub. No.: US 2010/0033913 A1
(43) Pub. Date: Feb. 11, 2010

(54) INTERFACE PROTECTIVE COVER OF ELECTRONIC DEVICE

(75) Inventor: Xiang Cao, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/233,848

(22) Filed: Sep. 19, 2008

(30) Foreign Application Priority Data
Aug. 11, 2008 (CN) 200810303654.6

(51) Int. Cl. H05K 5/03; H01R 13/44

(52) U.S. Cl. 361/679.4; 439/135

(57) ABSTRACT

An exemplary electronic device includes a chassis and at least one interface protective cover. The chassis includes at least one interface. Each of the at least one interface protective cover includes a shielding portion for covering the at least one interface, and a fastening portion extending from the shielding portion and for engaging with the at least one interface. Each of the at least one interface protective cover is detachably engaged with each of the at least one interface that is not being used.

### BACKGROUND

1. Field of the Invention

The present invention relates to an interface protective cover of an electronic device.

2. Description of Related Art

With the rapid development of science and technology, electronic devices, such as desktop computers, notebook computers, and servers, employ more and more interfaces, such as universal serial bus (USB) interfaces to connect peripheral equipment, such as printers, external modems, scanners, flash drives, mobile phones, mouse devices, and keyboards.

However, unused interfaces may be idle for a long time and exposed to the environment. Electrical characteristics of the interfaces may be affected or damaged by dust, water, and other harmful substances in the air.

What is needed is to provide an interface protective cover of an electronic device.

### BRIEF DESCRIPTION OF THE DRAWINGS

FIG. 1 is an exploded, isometric view of an embodiment of an electronic device, the electronic device including a chassis and a plurality of interface protective covers.

FIG. 2 is an enlarged view of circled portion 11 of FIG. 1.

FIG. 3 is an enlarged, isometric view of an interface protective cover of the electronic device of FIG. 1.

FIG. 4 is an assembled view of the electronic device of FIG. 1.

### DETAILED DESCRIPTION

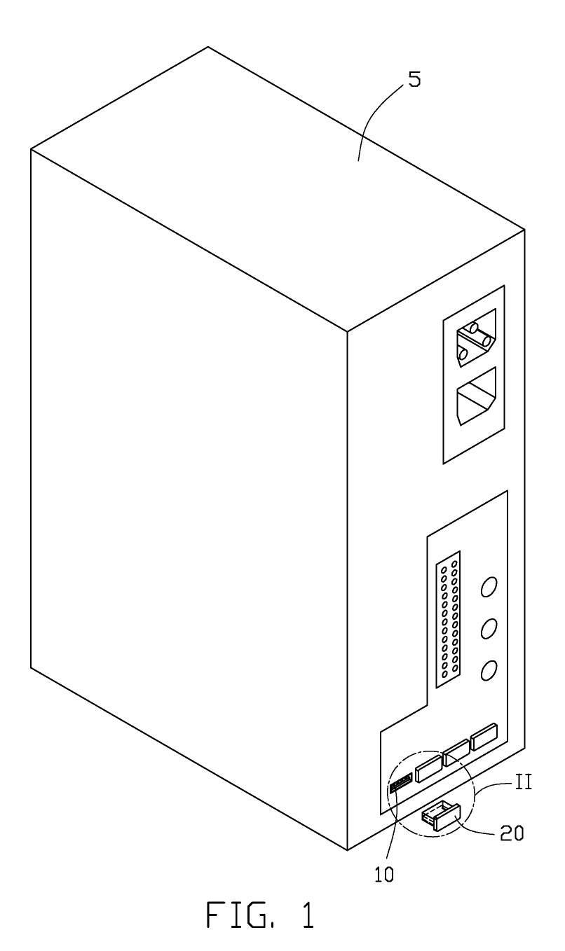

Referring to FIG. 1, an embodiment of an electronic device includes a chassis 5 and a plurality of interface protective covers 20. The chassis 5 includes a plurality of interfaces 10. In one embodiment, the plurality of interfaces 10 comprises USB interfaces. The plurality of interface protective covers 20 may be made of rubber or plastic materials.

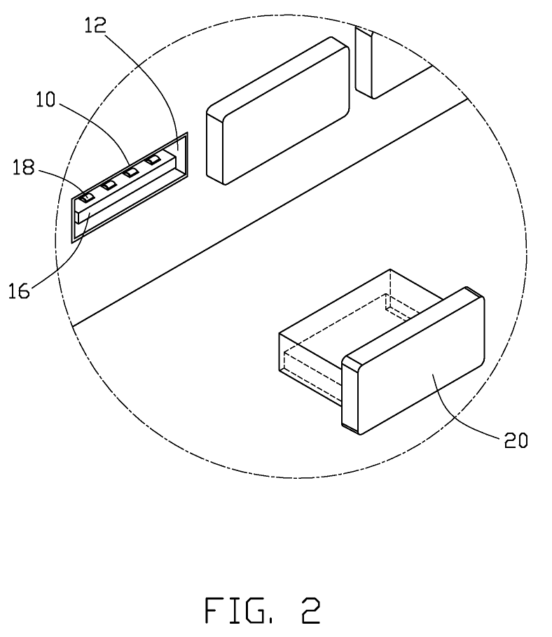

Referring to FIG. 2, each of the interfaces 10 includes a metal shell 12, a joint portion 16 accommodated in the metal shell 12, and a plurality of electrical terminals 18 mounted on a top wall of the joint portion 16. A space is defined between the metal shell 12 and the joint portion 16, for accommodating a USB plug (not shown) therein. The space includes a first portion defined between the metal shell 12 and the top wall of the joint portion 16, and a pair of second portions defined between the metal shell 12 and sidewalls of the joint portion 16. The plurality of electrical terminals 18 is configured for connecting with terminals of the USB plug.

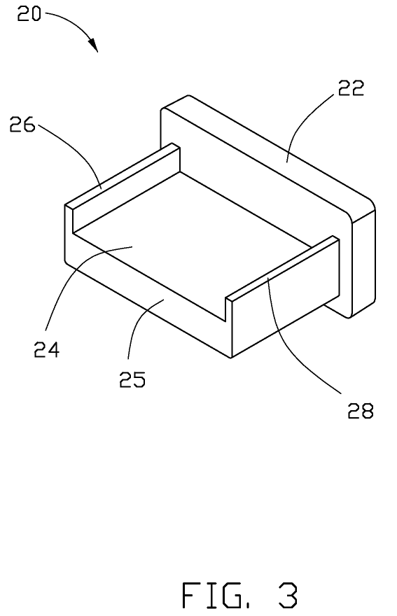

Referring to FIG. 3, each of the interface protective covers 20 includes a shielding portion 22 and a fastening portion 24 extending perpendicularly from the shielding portion 22. The fastening portion 24 includes a base plate 25 and two side plates 26, 28 extending perpendicularly from opposite edges of the base plate 25. A thickness of the base plate 25 is substantially equal to a width of the first portion of the space of the interface 10. A thickness of the side plates 26, 28 is substantially equal to a width of the second portions of the space of the interface 10.

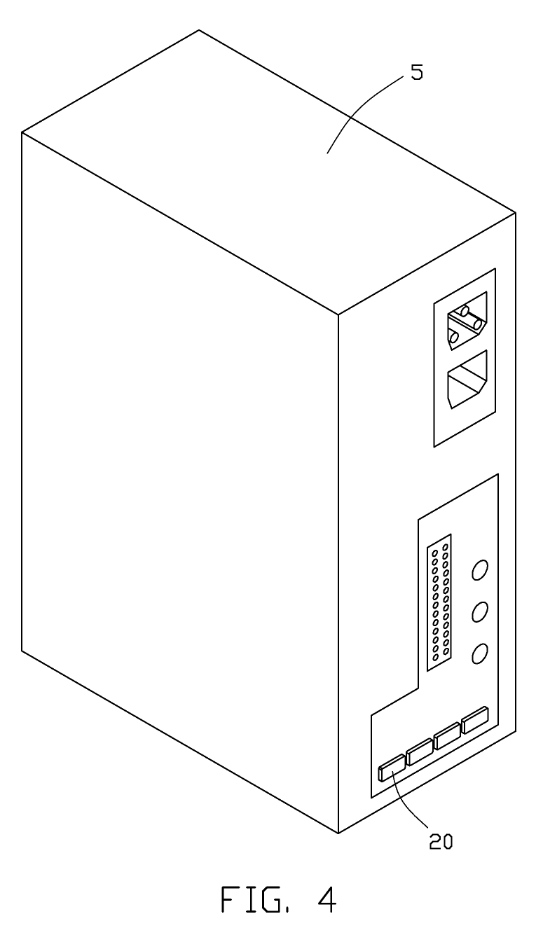

Referring also to FIG. 4, when the interface 10 is not in use, the fastening portion 24 of the interface protective cover 20 is inserted into the interface 10, with the base plate 25 interferentially received in the first portion of the interface 10, and the side plates 26, 28 interferentially received in the second portions of the interface 10. The shielding portion 22 of the interface protective cover 20 shields the interface 10 to protect it from being damaged by dust, water, and other harmful substances.

In another embodiment, only a base plate 25 extends from the shielding portion 22 to engage in the interface 10. In yet another embodiment, only a pair of side plates 26, 28 extends from the shielding portion 22, or only a side plate 26 or 28 extends from the shielding portion 22, to engage in the interface 10.

It is to be understood, however, that even though numerous characteristics and advantages of the embodiments have been set forth in the foregoing description, together with details of the structure and function of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. An electronic device comprising:
a chassis comprising at least one interface; and
at least one interface protective cover comprising:
a shielding portion for covering the at least one interface; and
a fastening portion extending from the shielding portion and for engaging with the at least one interface;
wherein each of the at least one interface protective cover is detachably engaged with each of the at least one interface that is not being use.

2. The electronic device as claimed in claim 1, wherein the at least one interface is a universal serial bus (USB) interface; the fastening portion of each of the at least one interface protective cover comprises a base plate and two side plates extending perpendicularly from opposite edges of the base plate, the base plate and the two side plates are interferentially engaged in the interface.

3. The electronic device as claimed in claim 1, wherein the at least one interface is a USB interface; the fastening portion of each of the at least one interface protective cover comprises a base plate, the base plate is inteferentially engaged in the interface.

4. The electronic device as claimed in claim 1, wherein the at least one interface is a USB interface; the fastening portion of each of the at least one interface protective cover comprises two side plates, the two side plates are inteferentially engaged in the interface.

5. The electronic device as claimed in claim 1, wherein the at least one interface is a USB interface; the fastening portion of each of the at least one interface protective cover comprises a side plate, the side plate is inteferentially engaged in the interface.

6. The electronic device as claimed in claim 1, wherein the interface protective cover is made of a rubber material.

7. The electronic device as claimed in claim 1, wherein the interface protective cover is made of a plastic material.

8. An interface protective cover, comprising:
a shielding portion; and
a fastening portion extending from the shielding portion and for being inserted into an idle interface of an electronic device.

9. The interface protective cover as claimed in claim 8, wherein the fastening portion comprises a base plate and two side plates extending perpendicularly from opposite edges of the base plate.

10. The interface protective cover as claimed in claim 8, wherein the fastening portion comprises a base plate.

11. The interface protective cover as claimed in claim 8, wherein the fastening portion comprises two side plates.

12. The interface protective cover as claimed in claim 8, wherein the fastening portion comprises a side plate.

13. The interface protective cover as claimed in claim 8, wherein the interface protective cover is made of a rubber material.

14. The interface protective cover as claimed in claim 8, wherein the interface protective cover is made of a plastic material.
